(19) United States
(12) Patent Application Publication
(10) Pub. No.: US 2025/0006567 A1
(43) Pub. Date: Jan. 2, 2025

(54) SEMICONDUCTOR PACKAGE

(71) Applicant: Samsung Electronics Co., Ltd., Suwon-si (KR)

(72) Inventor: Eunsu LEE, Suwon-si (KR)

(73) Assignee: Samsung Electronics Co., Ltd., Suwon-si (KR)

(21) Appl. No.: 18/394,750

(22) Filed: Dec. 22, 2023

(30) Foreign Application Priority Data
Jun. 29, 2023 (KR) 10-2023-0084125

(51) Int. Cl. H01L 23/13; H01L 21/48; H01L 23/00; H01L 23/31; H01L 25/16

(52) U.S. Cl. CPC H01L 23/13; H01L 21/481; H01L 23/3128; H01L 24/16; H01L 25/16; H01L 2224/16227

(57) ABSTRACT

A semiconductor package includes a substrate including a first surface and a second surface facing each other, a semiconductor chip on the substrate, a passive element disposed spaced apart from the semiconductor chip in a first direction parallel to the first surface of the substrate, and a first insulating pattern on an edge region of the first surface. The substrate includes a recessed portion formed on the first surface, the passive element vertically overlaps the recess portion, and the first insulating pattern protrudes in a second direction perpendicular to the first surface of the substrate.

### CROSS-REFERENCE TO RELATED APPLICATIONS

This U.S. non-provisional patent application claims priority under 35 U.S.C. § 119 to Korean Patent Application No. 10-2023-0084125, filed on Jun. 29, 2023, in the Korean Intellectual Property Office, the entire contents of which are hereby incorporated by reference.

### BACKGROUND OF THE INVENTION

Inventive concepts relate to a semiconductor package, for example a semiconductor package including a passive element.

Described is a semiconductor package to implement an integrated circuit chip useful in electronic products. Typically, a semiconductor package is configured such that a semiconductor chip is mounted on a printed circuit board (PCB) and bonding wires or bumps are used to electrically connect the semiconductor chip to the printed circuit board. Diverse research on improving the reliability and miniaturization of semiconductor packages has been conducted with the development of the electronic industry.

### SUMMARY

Some example embodiments of inventive concepts relate to a semiconductor package structure without an unfilled region of a molding layer when a passive element is mounted therein, and to a method of manufacturing a semiconductor package with improved efficiency. Problems to be solved by inventive concepts are not limited to the above-mentioned problems, and other problems not mentioned will be clearly understood by those ordinarily skilled in the art from the following description.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

Terms used in the embodiments may be interpreted as having meanings commonly understood by those ordinarily skilled in the art unless otherwise defined.

A semiconductor package according to some example embodiments of inventive concepts may include a substrate including a first surface and a second surface facing each other, a semiconductor chip on the substrate, a passive element apart from the semiconductor chip in a first direction parallel to the first surface of the substrate, and a first insulating pattern on an edge region of the first surface, wherein the substrate may have a recessed portion on the first surface, the passive element may vertically overlap the recessed portion, and the first insulating pattern may protrude in a second direction perpendicular to the first surface of the substrate.

A semiconductor package according to some example embodiments of inventive concepts may include a substrate, a semiconductor chip on the substrate, and a passive element apart from the semiconductor chip in a first direction parallel to an upper surface of the substrate, wherein the substrate may include a recessed portion at an upper portion thereof, the passive element may be vertically apart from the substrate with the recess portion therebetween, the passive element may include a first side surface facing a side surface of the semiconductor chip and a second side surface perpendicular to the side surface of the semiconductor chip when viewed in a plan view, the first side surface and the second side surface may have a first width and a second width, respectively, and the first width may be narrower than the second width.

A semiconductor package according to some example embodiments of inventive concepts may include a substrate including a first surface and a second surface facing each other, a semiconductor chip on the substrate, a passive element apart from the semiconductor chip in a first direction parallel to the first surface of the substrate, an insulating pattern on an edge region of the first surface, a molding layer on the substrate, and connection terminals disposed between the semiconductor chip and the first surface of the substrate, wherein the substrate may have a recessed portion on the first surface, the passive element may overlap the recessed portion vertically and include a first side surface facing a side surface of the semiconductor chip and a second side surface perpendicular to the side surface of the semiconductor chip when viewed in a plan view, the first side surface and the second side surface may have a first width and a second width, respectively, the first width may be narrower than the second width, the insulating pattern may protrude by 10 μm to 18 μm in a second direction perpendicular to the second surface of the substrate, and the molding layer may fill the recessed portion and surround side surfaces of the connection terminals.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to an example embodiments of some inventive concepts.

FIG. 2 is a cross-sectional view taken along the line A-A′ of FIG. 1.

FIG. 3 is an enlarged view of a portion ‘CU’ of FIG. 2.

FIGS. 4A to 8B are views for explaining a method of manufacturing a semiconductor package according to example embodiments of inventive concepts, and FIGS. 4B, 5B, 6B, 7B, and 8B are cross-sectional views taken along line A-A′ of FIGS. 4A, 5A, 6A, 7A, and 8A, respectively.

FIG. 9 is a plan view of a semiconductor package according to a comparative example.

### DETAILED DESCRIPTION

Hereinafter, the inventive concepts will be described in detail by describing non-limiting example embodiments of inventive concepts with reference to the accompanying drawings.

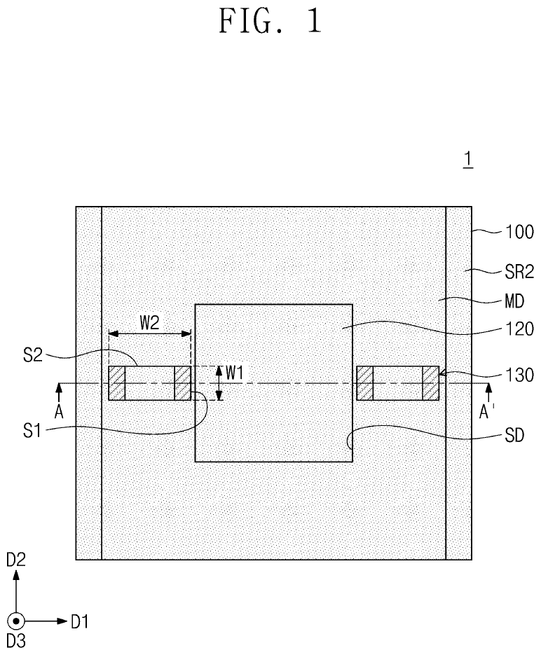

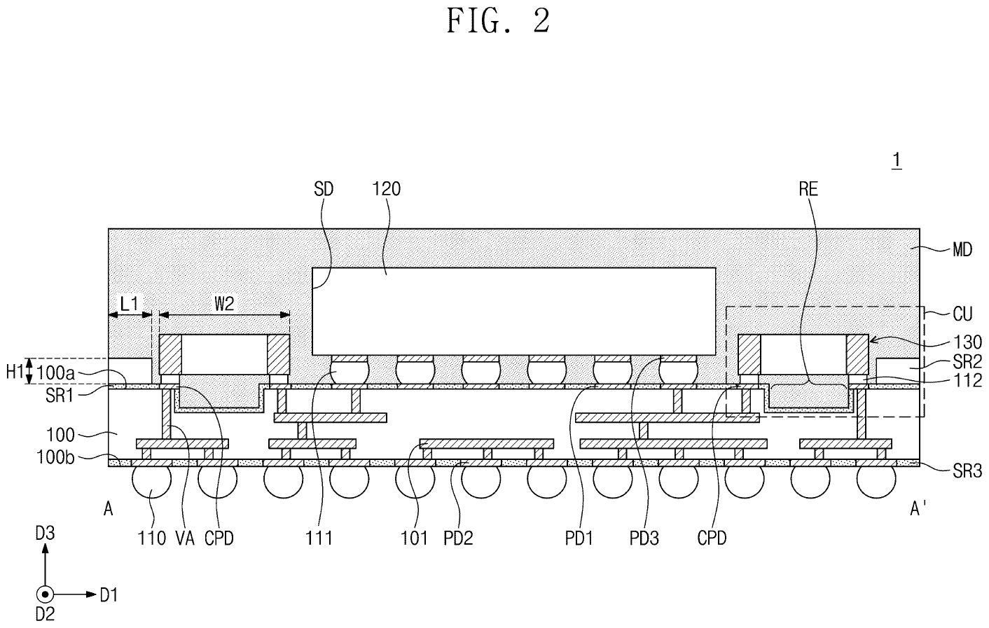

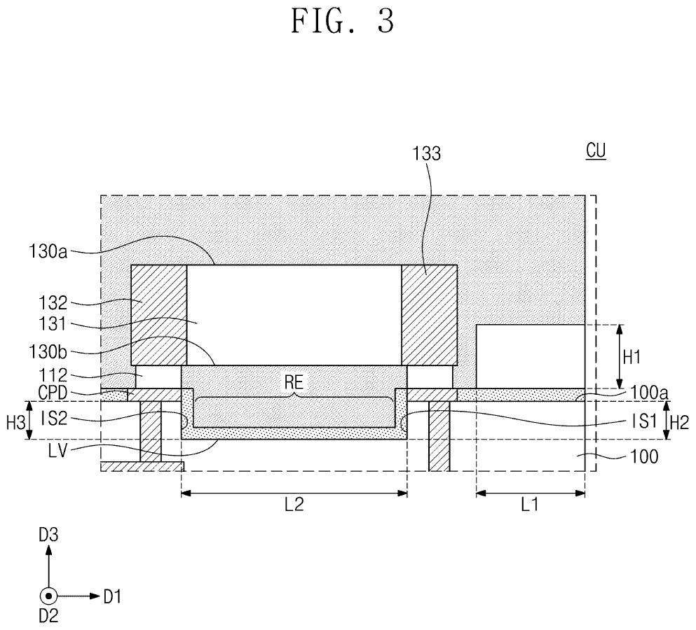

FIG. 1 is a plan view of a semiconductor package according to an example embodiments of some inventive concepts. FIG. 2 is a cross-sectional view taken along the line A-A′ of FIG. 1. FIG. 3 is an enlarged view of a portion ‘CU’ of FIG. 2.

Referring to FIGS. 1 to 3, a semiconductor package 1 according to the inventive concepts may include a package substrate 100, a semiconductor chip 120, a passive element 130, and a molding layer MD.

In this specification, a first direction D1 is defined as one direction parallel to an upper surface of the package substrate 100. A second direction D2 is defined as a direction parallel to the upper surface of the package substrate 100 and perpendicular to the first direction D1. A third direction D3 is defined as one direction perpendicular to the upper surface of the package substrate 100.

The package substrate 100 may be, for example, a printed circuit board (PCB). The package substrate 100 may include metal patterns 101, vias VA, and recessed portions RE. The metal patterns 101 and the vias VA may include, for example, titanium (Ti), copper (Cu), nickel (Ni), or gold (Au). Although not shown, the package substrate 100 may include an insulating layer, and the insulating layer may include glass fiber or resin, but example embodiments are not limited thereto

The package substrate 100 may include a first surface 100a and a second surface 100b that face each other. The first surface 100a may be the same or substantially the same as the upper surface of the package substrate 100. The second surface 100b may be the same or substantially the same as a lower surface of the package substrate 100. For example, the first surface 100a may be in contact with a lower surface of a first insulating pattern SR1 to be described later.

The package substrate 100 may include a plurality of first pads PD1 on the first surface 100a, a plurality of connection pads CPD, and a plurality of second pads PD2 on the second surface 100b. The first pads PD1, the connection pads CPD, and the second pads PD2 may be electrically connected to the metal patterns 101 inside the package substrate 100 through vias VA, respectively.

External connection terminals 110 may be respectively disposed on the second pads PD2. The external connection terminals 110 may be electrically connected to the package substrate 100 through the second pads PD2. The external connection terminals 110 may include, for example. solder balls or solder bumps. The external connection terminals 110 may be provided in a form of a ball grid array (BGA), fine ball-grid array (FBGA) or land grid array (LGA) depending on the type and arrangement of external connection terminals 110. The external connection terminal 110 may include at least one of tin (Sn), silver (Ag), copper (Cu), nickel (Ni), bismuth (Bi), indium (In), antimony (Sb), or cerium (Ce).

The package substrate 100 may include a recessed portion RE formed on the first surface 100a. Details of the recessed portion RE will be described later.

A first insulating pattern SR1 may be provided on the first surface 100a of the package substrate 100 and the recessed portion RE. The first insulating pattern SR1 may be disposed in a form exposing the plurality of first pads PD1 and the plurality of connection pads CPD. The first insulating pattern SR1 may include, for example, a solder resist. The first insulating pattern SR1 may be, for example, disposed closer to the package substrate 100 than the second insulating pattern SR2 to be described later.

The semiconductor chip 120 may be provided on the first surface 100a of the package substrate 100. The semiconductor chip 120 may be, for example, a logic chip. The semiconductor chip 120 may be, for example, a central processing unit (CPU), a graphics processing unit (GPU), or an application specific integrated circuit (ASIC). A plurality of chip pads PD3 may be disposed on a lower surface of the semiconductor chip 120.

First connection terminals 111 may be disposed between the package substrate 100 and the semiconductor chip 120. For example, the first connection terminals 111 may be interposed between and may be in contact with the first pad PD1 and the chip pad PD3. The semiconductor chip 120 may be electrically connected to the package substrate 100 through the first connection terminals 111. The first connection terminals 111 may include a metal material the same as, substantially the same as, or similar to the external connection terminal 110.

The passive element 130 may be disposed on the first surface 100a of the package substrate 100. The passive element 130 may be disposed apart from the semiconductor chip 120 in the first direction D1. A plurality of passive elements 130 may be disposed apart from each other in the first direction D1 with the semiconductor chip 120 interposed therebetween. In addition, the passive element 130 may be disposed to overlap the recessed portion RE in the third direction D3.

The passive element 130 may include a first side surface S1 facing the side surface SD of the semiconductor chip 120 and a second side surface S2 perpendicular to the side surface SD of the semiconductor chip 120 when viewed in a plan view. The first side surface S1 may be one surface of the passive element 130 parallel to the second direction D2. The second side surface S2 may be the other surface of the passive element 130 parallel to the first direction D1. When viewed in a plan view, the first side surface S1 and the second side surface S2 may be perpendicular or substantially perpendicular to each other.

The first side surface S1 of the passive element 130 may have a first width W1, and the second side surface S2 may have a second width W2. For example, the first width W1 may correspond to a length of one side of the passive element 130 facing the side SD of the semiconductor chip 120 in the second direction D2. The second width W2 may correspond to a length of the other surface of the passive element 130 perpendicular to the side SD of the semiconductor chip 120 in the first direction D1. The first width W1 may be smaller than the second width W2. The passive element 130 may include, for example, a capacitor, an inductor, and a resistor, and may be provided in the plural to improve performance of the semiconductor chip 120, but example embodiments are not limited thereto.

Second connection terminals 112 may be disposed on a lower surface of the passive element 130. For example, the second connection terminals 112 may be interposed between the connection pads CPD disposed on the first surface 100a and the passive element 130, and may be in contact with the connection pads CPD disposed on the first surface 100a and the passive element 130. The passive element 130 may be electrically connected to the package substrate 100 through the second connection terminals 112. The second connection terminals 112 may include a metal material the same as, substantially the same as, or similar to that of the external connection terminal 110.

A second insulating pattern SR2 may be disposed on an edge region of the first surface 100a of the package substrate 100. For example, the second insulating pattern SR2 may be disposed on an edge region of the first insulating pattern SR1 provided on the package substrate 100. The second insulating pattern SR2 may be disposed apart from the passive element 130 in the first direction D1. For example, the second insulating pattern SR2 may be disposed on an edge region of the first surface 100a of the package substrate 100 parallel to the first side surface S1 of the passive element 130. On the other hand, the second insulating pattern SR2 may not be disposed on one surface of the package substrate 100 parallel to the second side surface S2 of the passive element 130. The second insulating pattern SR2 and the first insulating pattern SR1 may be in contact with each other, and an interface therebetween may not be visually distinguished.

The second insulating pattern SR2 may protrude in the third direction D3. According to some example embodiments, a level of an upper surface of the second insulating pattern SR2 may be higher than a level of upper surfaces of the second connection terminals 112 and a level of the lower surface of the passive element 130. A height H1 of the second insulating pattern SR2 in the third direction D3 may range from about 10 μm to about 18 μm. A length L1 of the second insulating pattern SR2 in the first direction D1 may be about 50 μm or more. The second insulating pattern SR2 may include, for example, solder resist.

A thickness of a region where the second insulating pattern SR2 vertically overlaps the package substrate 100 in the third direction D3 may be equal to the height H1 of the second insulating pattern SR2 in the third direction D3 compared to other regions. The thickness of the edge region of the semiconductor package 1 may become thick due to the second insulating pattern SR2 protruding in the third direction D3, thereby reducing or preventing warping of the semiconductor package.

The molding layer MD may be, for example, provided on the first surface 100a of the package substrate 100, the upper surface of the second insulating pattern SR2, and on the recessed portion RE. For example, the molding layer MD may be provided in a space between the semiconductor chip 120 and the package substrate 100, in a space between the passive element 130 and the recessed RE, and on the upper surface of the second insulating pattern SR2. For example, the molding layer MD may be disposed in a form surrounding side surfaces of the first connection terminals 111 disposed between the semiconductor chip 120 and the package substrate 100. The molding layer MD may include an insulating material, and the insulating material may include a material such as an epoxy molding compound or an adhesive material.

A third insulating pattern SR3 may be, for example, disposed on the second surface 100b of the package substrate 100. The third insulating pattern SR3 may be disposed to expose the second pads PD2. The third insulating pattern SR3 may include, for example, a solder resist.

Referring back to FIG. 3, the passive element 130 may include a dielectric 131, a first terminal 132, and a second terminal 133. The dielectric 131 may be interposed between the first terminal 132 and the second terminal 133. Although not shown, an inside of the dielectric 131 may have a multilayer structure including a plurality of metal electrodes. The dielectric 131 may include ceramic or the like.

The package substrate 100 may include a recessed portion RE on an upper portion thereof. A plurality of recessed portions RE may be provided on the upper portion of the package substrate 100. A recessed portion RE may include a first inner wall IS1, a second inner wall IS2, and a bottom surface LV. The first inner wall IS1 may be a portion connected to an edge portion of the first surface 100a of the package substrate 100. A height H2 of the first inner wall IS1 may be about 10 μm or more. The second inner wall IS2 may be a portion connected to a central region of the first surface 100a of the package substrate 100. The second inner wall IS2 may be spaced apart from the first inner wall IS1 in the first direction D1, and a height H3 of the second inner wall IS2 may be the same or substantially the same as the height H1 of the first inner wall IS1. The height H3 of the second inner wall IS1 may be about 10 μm or more.

The bottom surface LV may be a surface connecting the first inner wall IS1 and the second inner wall IS2. A level of the bottom surface LV may be positioned between a level of the first surface 100a and a level of the second surface 100b of the package substrate 100. The bottom surface LV may be closer to the first surface 100a than the second surface 100b. The bottom surface LV may be a surface parallel to the first surface 100a and the second surface 100b. A length L2 of the bottom surface LV may be 70% to 90% of a length of the passive element 130 in the first direction D1.

The first insulating pattern SR1 may be disposed on the first surface 100a, the first inner wall IS1, the second inner wall IS2, and the bottom surface LV of the package substrate 100. For example, the first insulating pattern SR1 may be disposed on regions of the recessed portion in addition to the first surface 100a of the package substrate 100, but example embodiments are not limited thereto.

Meanwhile, a level of an upper surface 130a of the passive element 130 may be higher than a level of an upper surface of the second insulating pattern SR2 described above. A level of a lower surface 130b of the passive element 130 may be lower than a level of a lower surface of the second insulating pattern SR2.

Referring back to FIGS. 1 and 2, the semiconductor package 1 according to some example embodiments of inventive concepts includes a recessed portion RE on an upper region of the package substrate 100 and a second insulating pattern SR2 on an edge region of the package substrate 100 and protruding in the third direction D3. When the package substrate 100 includes the recessed portion RE, the space between the passive element 130 and the package substrate 100 may be enlarged. In addition, when the molding layer MD is filled, the space between the passive element 130 and the package substrate 100 may be filled with the molding layer MD without an empty space remaining therein. In addition, the second insulating pattern SR2 may be provided on the edge region of the package substrate 100, and thus a speed at which the molding layer MD fills the region other than the region between the semiconductor chip 120 and the package substrate 100 may be controlled. Accordingly, a speed at which the semiconductor package 1 is filled with the molding layer MD may be uniform over the entire region of the semiconductor package 1.

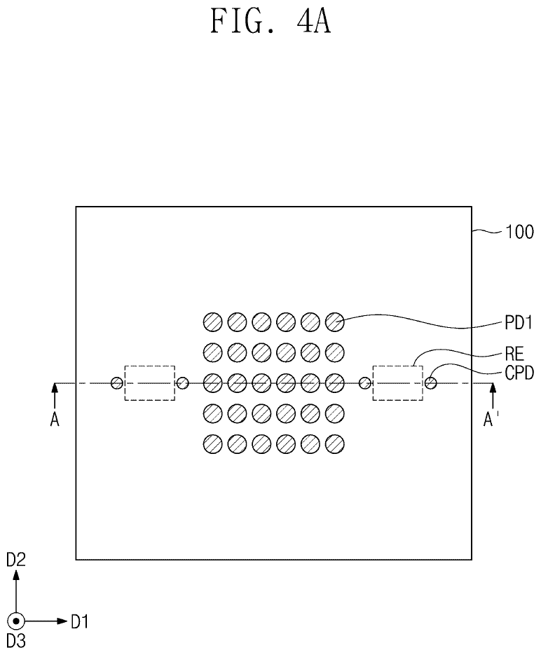

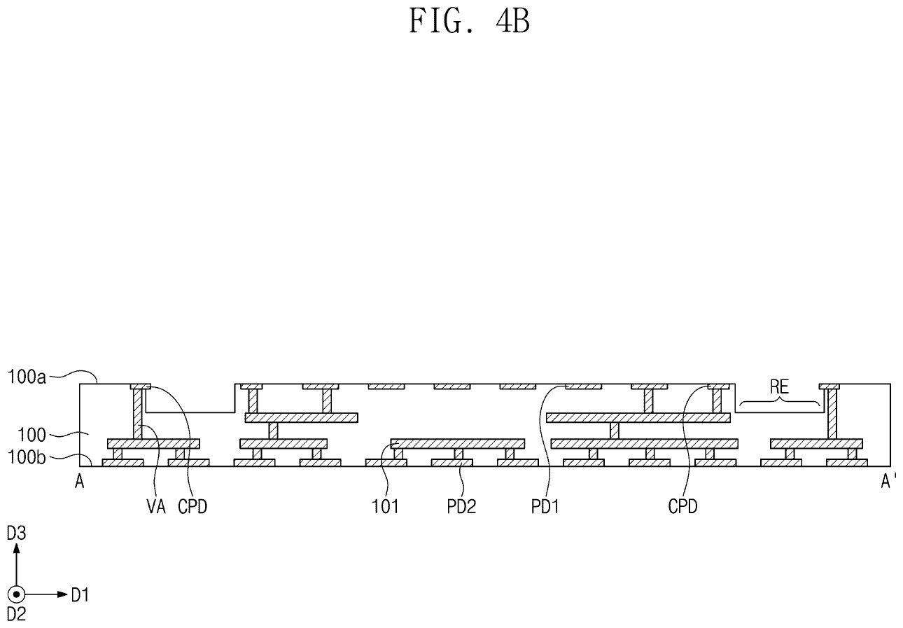

FIGS. 4A to 8B are views for explaining a method of manufacturing a semiconductor package according to example embodiments of inventive concepts, and FIGS. 4B, 5B, 6B, 7B, and 8B are cross-sectional views taken along line A-A′ of FIGS. 4A, 5A, 6A, 7A, and 8A, respectively.

Referring to FIGS. 4A and 4B, a package substrate 100 may be provided. The package substrate 100 may include metal patterns 101, vias VA, a first pad PD1, a second pad PD2, and connection pads CPD. A recessed portion RE may be formed on the package substrate 100. Although not shown, a mask pattern selectively exposing a portion where the recessed portion RE is to be formed may be formed on the first surface 100a. Thereafter, the package substrate 100 may selectively etched using the mask pattern as an etch mask to form the recessed RE. The recessed portion RE may be formed using a dry or wet etching process, but example embodiments are not limited thereto.

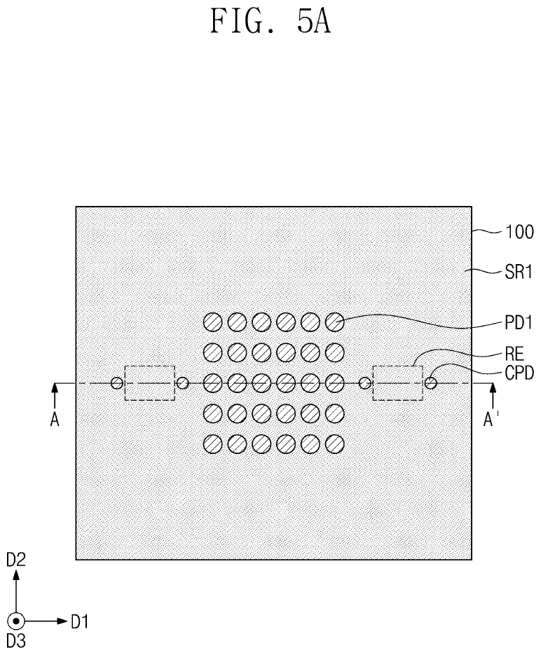

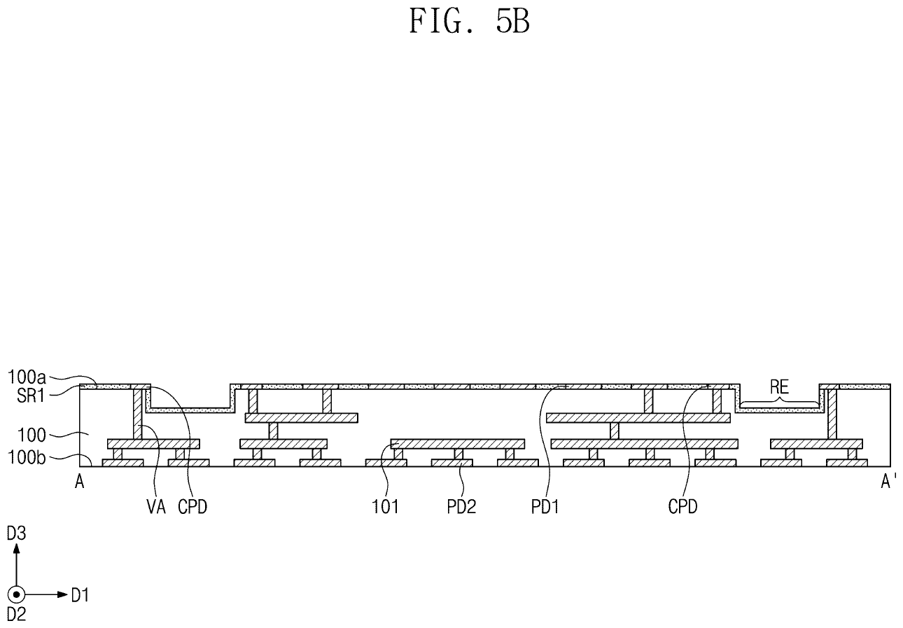

Referring to FIGS. 5A and 5B, a first insulating pattern SR1 may be formed on the first surface 100a of the package substrate 100 and the recessed portion RE. Although not shown, the first insulating layer may cover the first surface 100a of the package substrate 100 and the recess portion RE. Thereafter, the first insulating layer may be patterned to expose the first pad PD1 and the connection pads CPD, thereby forming the first insulating pattern SR1,

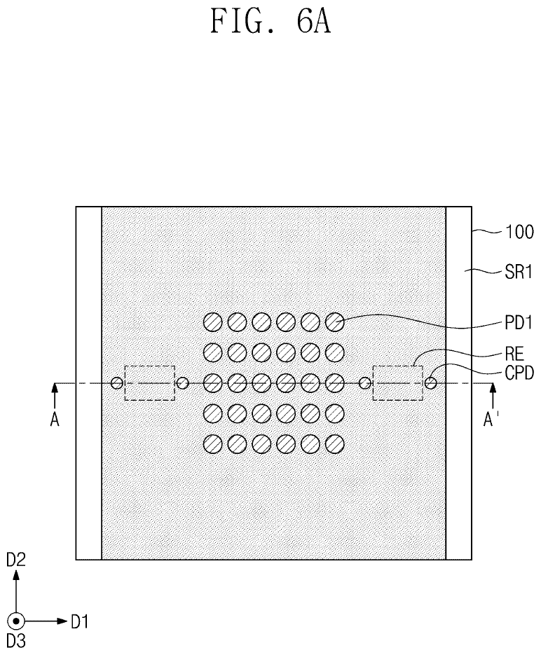

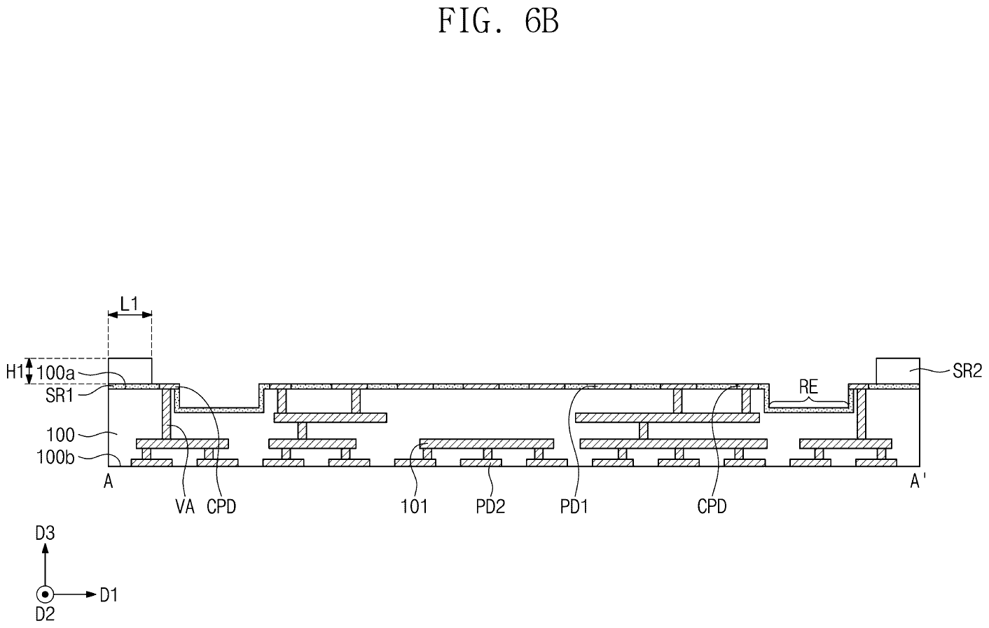

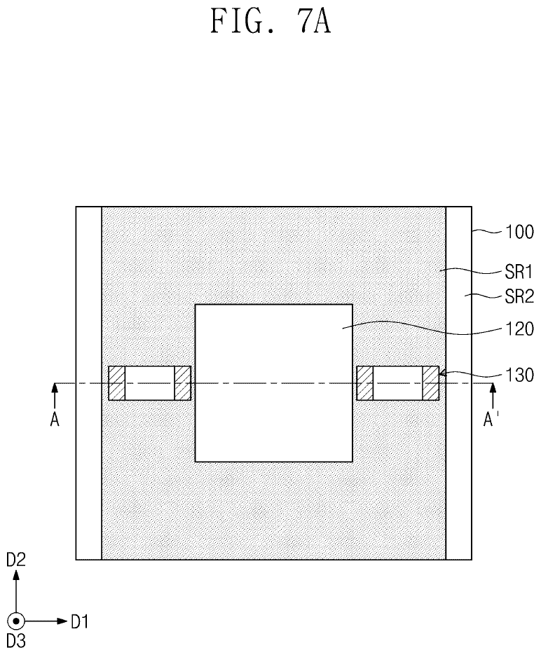

Referring to FIGS. 6A and 6B, a second insulating pattern SR2 may be formed on an edge region of the first surface 100a of the package substrate 100. The second insulating pattern SR2 may have a height H1 in a range of about 10 μm to about 18 μm in a third direction D3. The second insulating pattern SR2 may be formed such that a length L1 in a first direction D1 is about 50 μm or more. The height H1 of the second insulating pattern SR2 in the third direction D3 and the length L1 in the first direction D1 may be adjusted through an additional etching process.

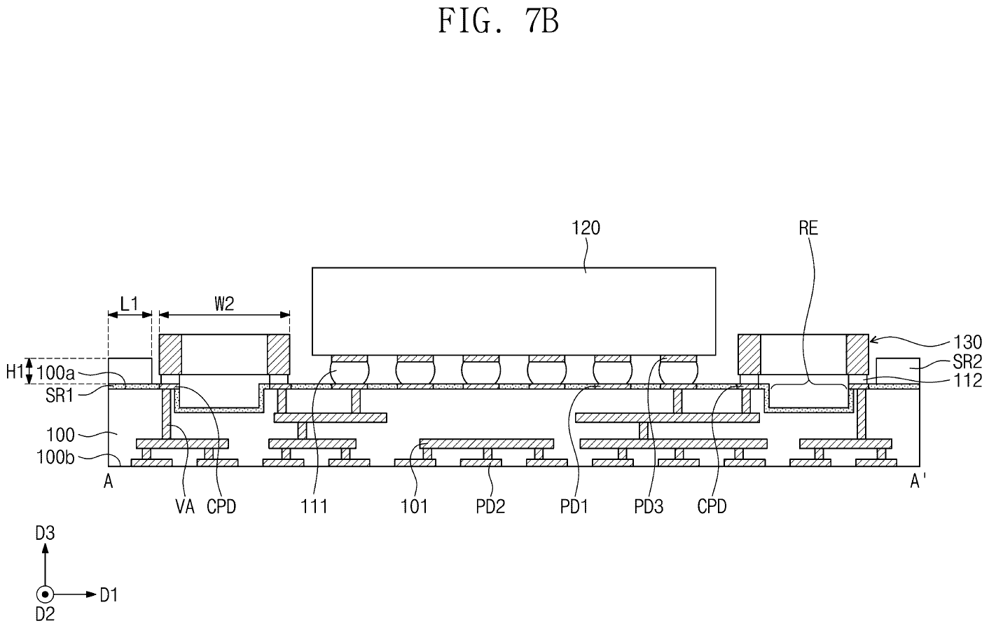

Referring to FIGS. 7A and 7B, a semiconductor chip 120 and a passive element 130 may be mounted on the package substrate 100. For example, chip pads PD3 may be formed on a lower surface of the semiconductor chip 120. The chip pads PD3 may be electrically connected to the first pads PD1 through first connection terminals 111, for example. The semiconductor chip 120 may be mounted on the package substrate 100 in a flip-chip manner, but example embodiments are not limited thereto.

Second connection terminals 112 may be formed on the plurality of connection pads CPD. Thereafter, the passive element 130 may be mounted on the package substrate 100 in such a way that second connection terminals 112 are attached to the lower surface of the passive element 130. The passive element 130 may be electrically connected to the package substrate 100 through the second connection terminals 112.

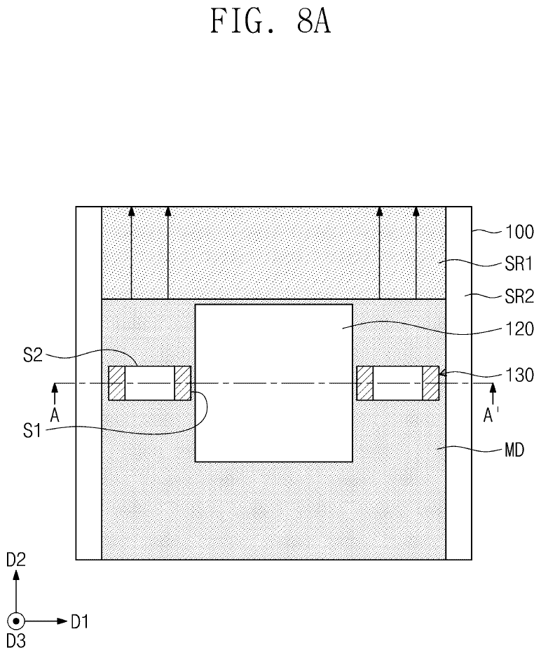

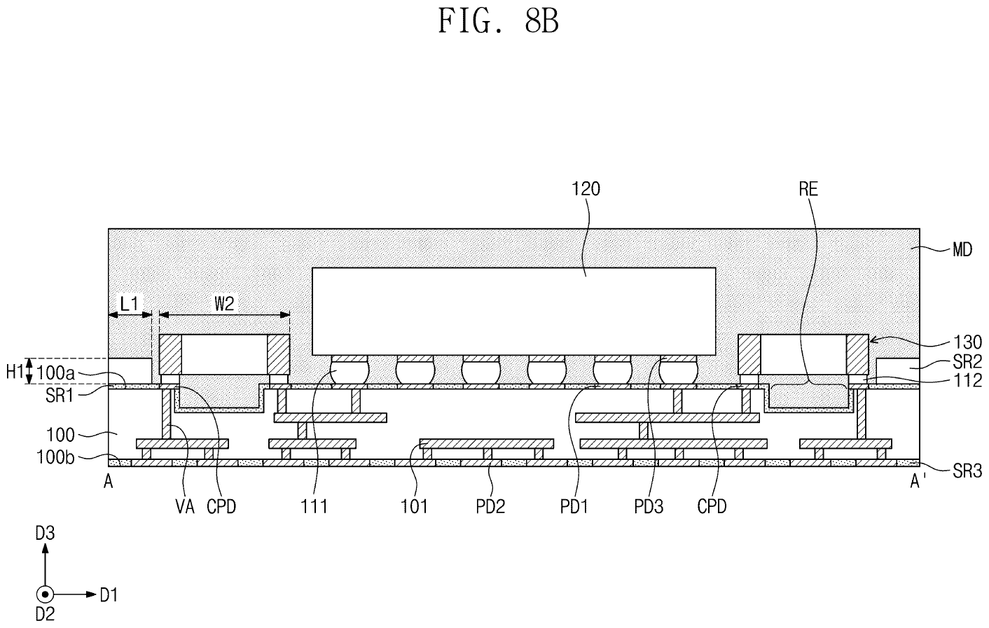

Referring to FIGS. 8A and 8B, although not shown, a third insulating layer may be formed on the second surface 100b of the package substrate 100. Thereafter, the third insulating layer may be patterned to expose the second pads PD2, thereby forming a third insulating pattern SR3.

A molding layer MD may be formed on the package substrate 100. For example, the molding layer MD may be formed in a space between the package substrate 100 and the semiconductor chip 120, in a space between the recessed portion RE and the passive element 130, and on the second insulating pattern SR2. When viewed in a plan view, a direction in which the molding layer MD is filled may be the same or substantially the same as the second direction D2. A direction in which the molding layer MD is filled may be perpendicular to one surface of the second side surface S2 of the passive element 130. A formation direction of the molding layer MD may be in a direction parallel to one surface of the first side surface S1 of the passive element 130. In this way, a process of filling an underfill in the space between the package substrate 100 and the semiconductor chip 120 may be omitted through a process of forming the molding layer MD, thereby improving process efficiency of the semiconductor package 1.

Then, referring back to FIG. 2, external connection terminals 110 may be attached to the second pads PD2 disposed on the second surface 100b of the package substrate 100, thereby complete the semiconductor package 1.

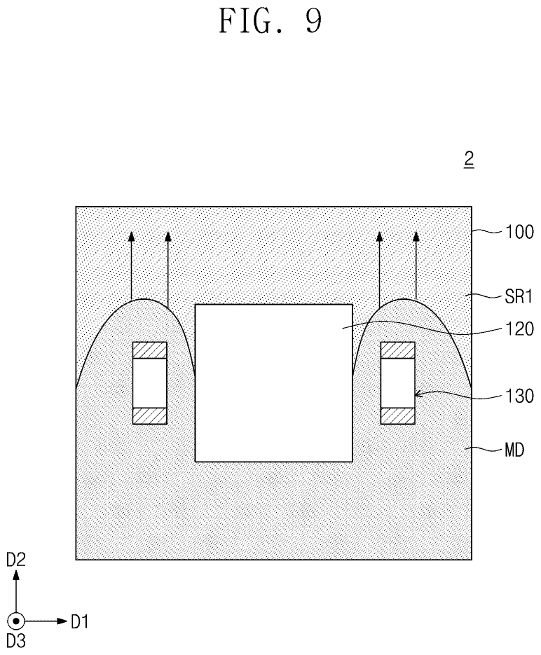

FIG. 9 is a plan view of a semiconductor package 2 according to a comparative example. Referring to FIG. 9, in the semiconductor package 2 according to the comparative example, when viewed in a plan view, a passive element 130 has been disposed such that a width of one side of the passive element 130 facing aa side of the semiconductor chip 120 is longer than a width of the other surface of the passive element 130 perpendicular to the side of the semiconductor chip 120. For example, a direction in which the molding layer MD is filled may be perpendicular or substantially perpendicular to the other surface of the passive element 130 having a short width. For example, the direction in which the molding layer MD is filled is parallel to one side of the passive element 130 having a long width. As a result, in the semiconductor package 2 according to the comparative example, the speed at which the molding layer MD fills the space between the passive element 130 and the package substrate 100 is higher than the speed at which the space between the semiconductor chip 120 and the package substrate 100 is filled, and thus there is a problem in that the molding layer MD is not filled in a region between the semiconductor chip 120 and the package substrate 100 compared to the region between the passive element 130 and the package substrate 100. As described above, when a filling degree of the molding layer MD is different depending on the region of the semiconductor package, reliability of the semiconductor package may be deteriorated and a defect in process quality may occur.

On the other hand, in the semiconductor package 1 according to example embodiments of inventive concepts, when viewed in a plan view, the passive element 130 is disposed such that the width of one surface of the passive element 130 facing the side of the semiconductor chip 120 is shorter than the width of the other surface of the passive element 130 perpendicular to the side of the semiconductor chip 120. For example, the other surface of the passive element 130 perpendicular to the side surface of the semiconductor chip 120 may be perpendicular to the direction in which the molding layer MD is filled. Therefore, the width of one surface of the passive element 130 facing the side surface of semiconductor chip 120 when the molding layer MD is filled in the semiconductor package 1 according to example embodiments of some inventive concepts is shorter than the width of one surface of the passive element 130 facing the side surface of semiconductor chip 120 when the molding layer MD is filled in the semiconductor package 2 according to the comparative example. As a result, the speed at which the molding layer MD fills the space between the passive element 130 and the package substrate 100 is slower in the semiconductor package 1 according to example embodiments of the present inventive concepts than in the semiconductor package 2 according to the comparative example. After the arrangement of the passive element 130 is different from that of the semiconductor package 2 according to the comparative example, when the molding layer MD is filled, a difference between the speed at which the molding layer MD fills the region between the passive element 130 and the package substrate 100 and the speed at which the region between the semiconductor chip 120 and the package substrate 100 is filled may be reduced. Therefore, the filling speed of the molding layer MD may be the same or similar in the entire region of the semiconductor package 1, and thus the space between the semiconductor chip 120 and the package substrate 100 may be filled with the molding layer MD without the empty space. As a result, reliability and quality of the semiconductor package 1 according to example embodiments may be improved compared to the semiconductor package according to the comparative example.

A semiconductor package according to an example embodiment of some inventive concepts includes the passive element vertically overlapping the recessed portion in the upper region of the package substrate and the insulating pattern protruding from the edge region of the upper surface of the package substrate. The recessed portion may be provided, and the gap between the passive element and the package substrate may be widened. Accordingly, the region between the passive element and the package substrate may be filled with the molding layer without empty space. In addition, the protruding insulating pattern may be provided on the edge region, and the filling speed of the molding layer in the region between the passive element and the package substrate may be slowed down. In addition, in the semiconductor package according to example embodiments of inventive concepts, the width of one surface of the passive element facing the side surface of the semiconductor chip is narrower than the width of the other surface of the passive element perpendicular to the side surface of the semiconductor chip. For example, the direction in which the molding layer is filled may be perpendicular or substantially perpendicular to the one surface of the long-width passive element. Accordingly, the difference between the speed at which the molding layer fills the region between the passive element and the package substrate and the speed at which the region between the semiconductor chip and the package substrate is filled may be reduced. As a result, the region between the semiconductor chip and the package substrate may be filled with the molding layer without the empty space remaining therein.

While example embodiments of inventive concepts are described above, a person ordinarily skilled in the art may understand that many modifications and variations are made without departing from the spirit and scope of the inventive concepts defined in the following claims. Accordingly, example embodiments of the inventive concepts should be considered in all respects as illustrative and not restrictive, with the spirit and scope of the inventive concepts being indicated by the appended claims.

What is claimed is:

1. A semiconductor package, comprising:
a substrate including a first surface and a second surface facing each other;
a semiconductor chip on the substrate;
a passive element apart from the semiconductor chip in a first direction parallel to the first surface of the substrate; and
a first insulating pattern on an edge region of the first surface;
wherein the substrate has a recessed portion on the first surface,
the passive element vertically overlaps the recessed portion, and
the first insulating pattern protrudes in a second direction perpendicular to the first surface of the substrate.

2. The semiconductor package of claim 1, further comprising a molding layer on the substrate, wherein the molding layer fills the recessed portion and space between the recessed portion and the passive element.

3. The semiconductor package of claim 1, wherein the semiconductor chip includes a logic chip.

4. The semiconductor package of claim 1, further comprising:
at least one connection terminal between the passive element and the first surface of the substrate.

5. The semiconductor package of claim 1, wherein a length of the recess portion in the second direction is 10 μm or more.

6. The semiconductor package of claim 1, wherein a length of the first insulating pattern in the second direction is 10 μm to 18 μm.

7. The semiconductor package of claim 1, wherein a length of the first insulating pattern in the first direction is 50 μm or more.

8. The semiconductor package of claim 1, wherein an upper surface of the passive element is above an upper surface of the first insulating pattern.

9. The semiconductor package of claim 1, wherein an upper surface of the first insulating pattern is above a lower surface of the passive element.

10. The semiconductor package of claim 4, wherein an upper surface of the first insulating pattern is above an upper surface of the connection terminal.

11. The semiconductor package of claim 1, further comprising:
a second insulating pattern between the first surface of the substrate and the first insulating pattern,
wherein at least one of the first insulating pattern and the second insulating pattern include a solder resist.

12. A semiconductor package, comprising:
a substrate;
a semiconductor chip on the substrate; and
a passive element apart from the semiconductor chip in a first direction parallel to an upper surface of the substrate,
wherein the substrate includes a recessed portion at an upper portion thereof,
the passive element is vertically apart from the substrate with the recess portion therebetween,
the passive element includes a first side surface facing a side surface of the semiconductor chip and a second side surface perpendicular to the side surface of the semiconductor chip when viewed in a plan view,
the first side surface and the second side surface have a first width and a second width, respectively, and
the first width is narrower than the second width.

13. The semiconductor package of claim 12, further comprising:
an insulating pattern on an edge region of the substrate,
wherein the insulating pattern protrudes in a second direction perpendicular to the upper surface of the substrate.

14. The semiconductor package of claim 13, wherein a lower surface of the passive element is below an upper surface of the insulating pattern.

15. The semiconductor package of claim 12, wherein the recessed portion has a third width in the first direction, and the third width is 70% to 90% of a length of the passive element in the first direction.

16. The semiconductor package of claim 13, wherein the insulating pattern extends in a direction parallel to the first side surface when viewed in a plan view.

17. A semiconductor package, comprising:
a substrate including a first surface and a second surface facing each other;
a semiconductor chip on the substrate;
a passive element apart from the semiconductor chip in a first direction parallel to the first surface of the substrate;
an insulating pattern on an edge region of the first surface;
a molding layer on the substrate; and
connection terminals between the semiconductor chip and the first surface of the substrate,
wherein the substrate has a recessed portion on the first surface,
the passive element overlaps the recessed portion vertically and includes a first side surface facing a side surface of the semiconductor chip and a second side surface perpendicular to the side surface of the semiconductor chip when viewed in a plan view,
the first side surface and the second side surface have a first width and a second width, respectively,
the first width is narrower than the second width,
the insulating pattern protrudes by 10 μm to 18 μm in a second direction perpendicular to the first surface of the substrate, and
the molding layer fills the recessed portion and surrounds side surfaces of the connection terminals.

18. The semiconductor package of claim 17, wherein an upper surface of the insulating pattern is above a lower surface of the passive element.

19. The semiconductor package of claim 17, wherein the passive element includes at least one of a capacitor, an inductor, and a resistor.

20. The semiconductor package of claim 17, wherein a length of the insulating pattern in the first direction is 50 μm or more.
